(19) United States
(12) Patent Application Publication
(10) Pub. No.: US 2025/0239478 A1
(43) Pub. Date: Jul. 24, 2025

(54) SEMICONDUCTOR MANUFACTURING APPARATUS AND METHOD OF MANUFACTURING SEMICONDUCTOR DEVICE

(71) Applicant: Mitsubishi Electric Corporation, Tokyo (JP)

(72) Inventor: Kota HASHIMOTO, Kumamoto (JP)

(73) Assignee: Mitsubishi Electric Corporation, Tokyo (JP)

(21) Appl. No.: 18/977,865

(22) Filed: Dec. 11, 2024

(30) Foreign Application Priority Data
Jan. 24, 2024 (JP) 2024-008858

(51) Int. Cl. H01L 21/683; H01L 21/268; H01L 21/67

(52) U.S. Cl. CPC H01L 21/6838; H01L 21/268; H01L 21/67115

(57) ABSTRACT

A semiconductor manufacturing apparatus includes a stage to which a semiconductor wafer including a protective portion and irradiated with laser light is mounted so that the protective portion is in contact with the stage, the stage having a vacuum suction region in which the semiconductor wafer is fixed and including a rigid based non-stick material provided on a side to be in contact with the protective portion of the semiconductor wafer, wherein the vacuum suction region is fitted within a circle having a radius {d−(b+c)}/d times a radius of the semiconductor wafer and being concentric with the semiconductor wafer, where d (mm) is the radius of the semiconductor wafer, b (mm) is a width of a foaming region in which the protective portion foams, c (mm) is a width of a deterioration region in which the rigid based non-stick material is deteriorated.

### BACKGROUND OF THE INVENTION

### Field of the Invention

The present disclosure relates to a semiconductor manufacturing apparatus to perform heat treatment and a method of manufacturing a semiconductor device.

### Description of the Background Art

In conventional technology, a stage having a plurality of open suction ports in an upper surface thereof and having a plurality of through holes extending from the upper surface to a lower surface and receiving therein respective lift pins is disclosed (e.g., Japanese Patent Application Laid-Open No. 2023-034622).

However, there has been a problem in that, when a semiconductor wafer is mounted to the stage and is subjected to heat treatment, a protective portion being in contact with the stage foams and sticks to the stage, making it difficult to remove the semiconductor wafer from the stage after heat treatment.

### SUMMARY

It is an object of the present disclosure to provide a semiconductor manufacturing apparatus enabling easy removal of a semiconductor wafer from a stage.

A semiconductor manufacturing apparatus according to the present disclosure includes a stage to which a semiconductor wafer is mounted so that a protective portion is in contact with the stage. The stage has a vacuum suction region and includes a rigid based non-stick material. The vacuum suction region is a region in which the semiconductor wafer including the protective portion and irradiated with laser light is fixed. The rigid based non-stick material is provided on a side to be in contact with the protective portion of the semiconductor wafer. The vacuum suction region is fitted within a circle having a radius that is {d−(b+c)}/d times a radius of the semiconductor wafer and being concentric with the semiconductor wafer, where d (mm) is the radius of the semiconductor wafer, b (mm) is a width of a foaming region in which the protective portion foams, c (mm) is a width of a deterioration region in which the rigid based non-stick material is deteriorated.

A method of manufacturing a semiconductor device according to the present disclosure includes: a protective portion formation step, a mounting step, a heat treatment step, and a lifting step. In the protective portion formation step, a protective portion is formed in a semiconductor wafer. In the mounting step, the semiconductor wafer is mounted to a stage including a rigid based non-stick material and having a vacuum suction region so that the protective portion is in contact with the rigid based non-stick material, the vacuum suction region being fitted within a circle having a radius that is {d−(b+c)}/d times a radius of the semiconductor wafer and being concentric with the semiconductor wafer, where d (mm) is the radius of the semiconductor wafer, b (mm) is a width of a foaming region in which the protective portion foams, c (mm) is a width of a deterioration region in which the rigid based non-stick material is deteriorated. In the heat treatment step, the semiconductor wafer is heat treated by being irradiated with laser light from a side opposite a side to be in contact with the stage. In the lifting step, a lift pin of the stage is moved to remove the semiconductor wafer from the stage.

The semiconductor wafer can easily be removed from the stage.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a top view of a semiconductor manufacturing apparatus according to Embodiment 1 of the present disclosure;

FIG. 2 is a cross-sectional view of the semiconductor manufacturing apparatus according to Embodiment 1 of the present disclosure and a semiconductor wafer;

FIG. 3 is a cross-sectional view of the semiconductor manufacturing apparatus according to Embodiment 1 of the present disclosure and the semiconductor wafer;

FIG. 4 is a cross-sectional view of the semiconductor manufacturing apparatus according to Embodiment 1 of the present disclosure and the semiconductor wafer;

FIG. 5 is a diagram for describing a vacuum suction region of the semiconductor manufacturing apparatus according to Embodiment 1 of the present disclosure;

FIG. 6 is a diagram for describing the vacuum suction region of the semiconductor manufacturing apparatus according to Embodiment 1 of the present disclosure;

FIG. 7 is a diagram showing a configuration of the semiconductor manufacturing apparatus according to Embodiment 1 of the present disclosure; and

FIG. 8 is a diagram showing a method of manufacturing a semiconductor device according to Embodiment 1 of the present disclosure.

### DESCRIPTION OF THE PREFERRED EMBODIMENTS

An embodiment of the present disclosure will be described below with reference to the accompanying drawings. The drawings are schematically shown, and sizes and positional correlations shown in different drawings are not necessarily limited to those shown and can be changed as appropriate. In description made below, similar components bear the same reference signs and have the same or similar names and functions. Detailed description thereof is thus sometimes omitted.

### Embodiment 1

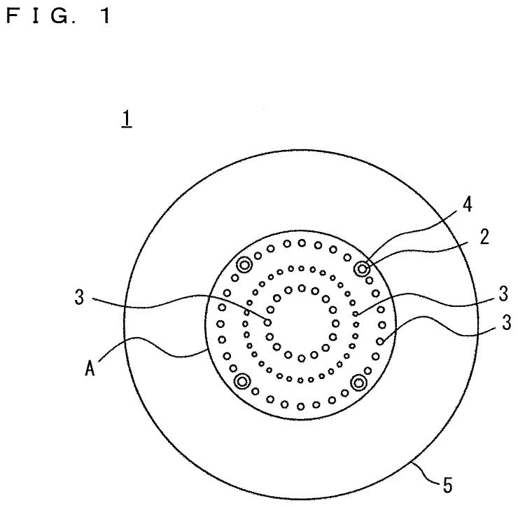

A semiconductor manufacturing apparatus 101 according to Embodiment 1 will be described with reference to FIGS. 1 to 7. FIG. 1 is a top view of the semiconductor manufacturing apparatus 101 according to Embodiment 1.

As illustrated in FIG. 1, the semiconductor manufacturing apparatus 101 according to the present embodiment includes a stage 1 and lift pins 2. A semiconductor wafer, which will be described below, is mounted to an upper surface of the stage 1. Based on the stage 1, a surface on a side on which the semiconductor wafer is provided is an upper surface. In FIG. 1, a surface on a front side of the page is the upper surface. A surface different from the upper surface, that is, a surface opposite the upper surface is a lower surface. A direction extending from the upper surface to the lower surface is a thickness direction. A surface other than the upper surface and the lower surface is a side surface. The same applies to the following description.

The stage 1 has suction holes 3, through holes 4, and an end 5. The semiconductor wafer, which will be described below, is mounted to the stage 1. The stage 1 is circular, for example. The stage 1 may not be circular and may have a quadrilateral shape or a polygonal shape other than the quadrilateral shape, for example. The stage 1 may be elliptical and may have a shape obtained by combining a plurality of curved and straight lines. The stage 1 is formed of quartz, for example. The stage 1 may be formed of glass.

The stage 1 has the suction holes 3. The suction holes 3 are provided in a central portion of the stage 1, for example. The suction holes 3 are holes in the upper surface of the stage 1. The number of suction holes 3 is two or more, for example. The suction holes 3 are arranged on a circumference, for example. The circumference on which the suction holes 3 are provided is a circumference of a circle concentric with the stage 1, for example. The suction holes 3 are arranged on circumferences of a plurality of concentric circles, for example. The suction holes 3 may not be arranged on a circumference.

A region in which the semiconductor wafer 6 is sucked and fixed to the stage 1 is a vacuum suction region. The suction holes 3 to fix the semiconductor wafer 6 to the stage 1 are provided in the vacuum suction region. The vacuum suction region is a region in a circle concentric with the stage 1, for example. In FIG. 1, the vacuum suction region is indicated as a region in a circle A. The vacuum suction region may not be circular.

The stage 1 has the through holes 4. The through holes 4 are provided in a central portion of the stage 1, for example. The number of through holes 4 is two or more, for example. The number of through holes 4 is four, for example. The through holes 4 are arranged on a circumference, for example. The through holes 4 are provided closer to the end 5 of the stage 1 than suction holes 3 provided closest to the center of all the suction holes 3 provided in the stage 1 are, for example.

The semiconductor manufacturing apparatus 101 includes the lift pins 2. The lift pins 2 are provided in a central portion of the stage 1, for example. The number of lift pins 2 is two or more, for example. The number of lift pins 2 is four, for example. The lift pins 2 are received in the respective through holes 4. The lift pins 2 are raised and lowered in the respective through holes 4. That is to say, the lift pins 2 are moved in the thickness direction in the respective through holes 4. The lift pins 2 are connected to an unillustrated drive apparatus and are moved up and down in the respective through holes 4, for example.

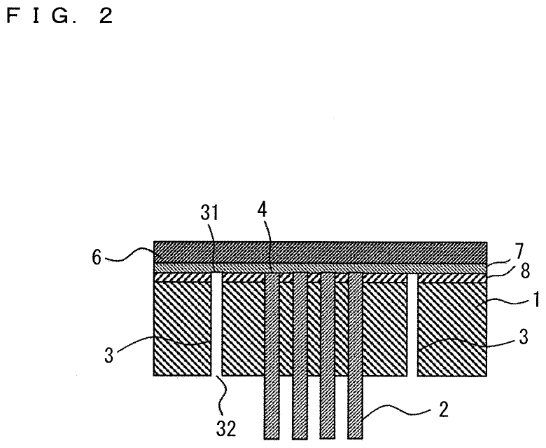

FIG. 2 is a cross-sectional view of the semiconductor manufacturing apparatus 101 according to Embodiment 1 and the semiconductor wafer 6. As illustrated in FIG. 2, the semiconductor wafer 6 is provided to the upper surface of the stage 1. In FIG. 2, a surface on an upper side of the page is the upper surface, and a surface on a lower side of the page is the lower surface.

The semiconductor wafer 6 includes a protective portion 7. The protective portion 7 is provided on a side of the lower surface of the semiconductor wafer 6. The semiconductor wafer 6 is mounted to the upper surface of the stage 1 with the protective portion 7 being provided on the side of the lower surface. The protective portion 7 is in contact with the stage 1. The semiconductor wafer 6 is mounted to the stage 1 so that the protective portion 7 is in contact with the stage 1.

The protective portion 7 protects the semiconductor wafer 6. The protective portion 7 also insulates the semiconductor wafer 6 and the stage 1 from each other. The protective portion 7 is formed of a resin, for example. The protective portion 7 is only required to be insulating and may be formed of a material other than the resin. The protective portion 7 may be insulating heat-resistant tape, for example.

As illustrated in FIG. 2, the stage 1 includes a rigid based non-stick material 8. The rigid based non-stick material 8 is provided in the upper surface of the stage 1. The rigid based non-stick material 8 is provided on a side to be in contact with the protective portion 7 of the semiconductor wafer 6. The rigid based non-stick material 8 is provided in the entire upper surface of the stage 1. The rigid based non-stick material 8 may be provided, in the upper surface of the stage 1, only on a side closer to the end 5 of the stage 1 than the vacuum suction region is.

The rigid based non-stick material 8 is provided to the stage 1 by application, for example. A material containing silicon and oxygen is used for the rigid based non-stick material 8, for example. The rigid based non-stick material 8 is mainly formed of silicon and oxygen, for example. The rigid based non-stick material 8 may contain a material other than silicon and oxygen.

Each of the suction holes 3 has one opening 31 and the other opening 32, for example. The one opening 31 is provided in the upper surface of the stage 1. The other opening 32 is provided in the lower surface of the stage 1. As illustrated in FIG. 2, each of the suction holes 3 is provided to extend from the upper surface to the lower surface of the stage 1, for example. Each of the suction holes 3 may be provided to be connected to other one or more of the suction holes 3 in the stage 1. That is to say, the number of one openings 31 may be two or more, and the other openings 32 may be smaller in number than the one openings 31. The other openings 32 may be provided in the side surface of the stage 1 and may be provided in a region of the upper surface of the stage 1 in which the semiconductor wafer 6 is not mounted.

The one opening 31 of each of the suction holes 3 is provided to be in contact with the protective portion 7 of the semiconductor wafer 6. The other opening 32 of each of the suction holes 3 is connected to an unillustrated vacuum pump, for example. The vacuum pump is driven to evacuate air from each of the suction holes 3, so that the semiconductor wafer 6 is sucked to the stage 1. That is to say, the suction holes 3 are provided, and air in the suction holes 3 are evacuated, so that the stage 1 can hold the semiconductor wafer 6. That is to say, the semiconductor manufacturing apparatus 101 has the vacuum suction region, so that the semiconductor wafer 6 can be fixed to the stage 1.

The through holes 4 are holes extending from the upper surface to the lower surface of the stage 1. The lift pins 2 are received in the respective through holes 4. The lift pins 2 are provided to extend from the upper surface to the lower surface of the stage 1. The lift pins 2 are provided to be received in the respective through holes 4. The lift pins 2 are connected to the unillustrated drive apparatus on a side of the lower surface, for example. The lift pins 2 can be moved up and down by the drive apparatus.

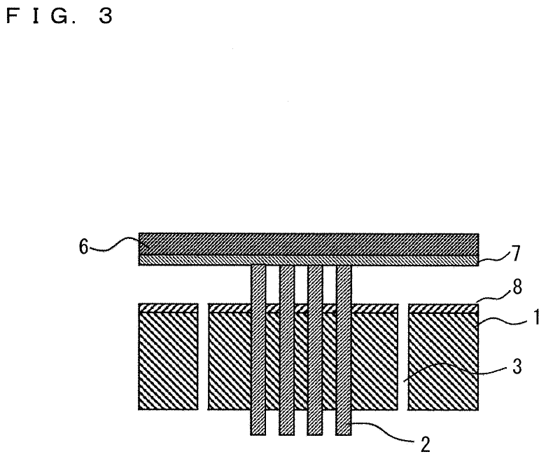

FIG. 3 is a side view of the semiconductor manufacturing apparatus 101 according to Embodiment 1 and the semiconductor wafer 6. FIG. 3 illustrates a case where the lift pins 2 have been moved up compared with a case illustrated in FIG. 2.

The lift pins 2 are moved up, so that the semiconductor manufacturing apparatus 101 can lift the semiconductor wafer 6. That is to say, the lift pins 2 are moved up, so that the semiconductor manufacturing apparatus 101 can remove the semiconductor wafer 6 from the stage 1. That is to say, the lift pins 2 are used to move the semiconductor wafer 6 away from the stage 1.

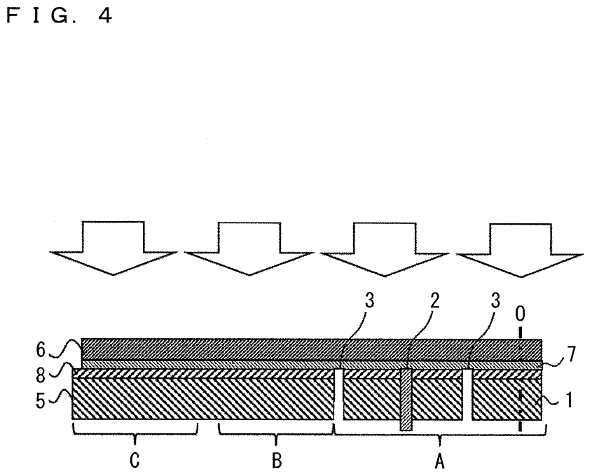

FIG. 4 is a cross-sectional view of the semiconductor manufacturing apparatus 101 according to Embodiment 1 and the semiconductor wafer 6. FIG. 4 illustrates a portion of the stage 1 and a portion of the semiconductor wafer 6. A reference sign “O” shown in FIG. 4 indicates the center of the semiconductor wafer 6. FIG. 4 is a diagram illustrating a cross section including the center O of the semiconductor wafer 6. FIG. 4 illustrates a portion from the center to the end 5 of the stage 1. The region in which the semiconductor wafer 6 is sucked to the stage 1 is the vacuum suction region. The center of the stage 1 preferably coincides with the center of the semiconductor wafer 6.

Arrows shown in FIG. 4 schematically show a direction of irradiation with laser light emitted from a laser apparatus, which will be described below. The upper surface of the semiconductor wafer 6 is irradiated with the laser light. That is to say, a side opposite a side to be in contact with the stage 1 of the semiconductor wafer 6 is irradiated with the laser light. A side opposite a side on which the protective portion 7 is provided of the semiconductor wafer 6 is irradiated with the laser light. The entire upper surface of the semiconductor wafer 6 is irradiated with the laser light. The semiconductor wafer 6 is irradiated with the laser light to be heat treated. That is to say, the semiconductor wafer 6 is subjected to laser annealing.

A foaming region B is a region in which the protective portion 7 of the semiconductor wafer 6 is likely to foam. The semiconductor wafer 6 will be at a temperature of approximately 1200° C. during laser annealing. The semiconductor wafer 6 will be at a temperature of approximately 1200° C., so that the protective portion 7 can foam. When the semiconductor wafer 6 is at a temperature of more than approximately 1200° C., the protective portion 7 is more likely to foam.

Even in a case where the semiconductor wafer 6 is at a temperature of less than approximately 1200° C., when the semiconductor wafer 6 has a small size in the thickness direction, heat is likely to be transferred to the protective portion 7, and the protective portion 7 is likely to foam. The protective portion 7 is more likely to foam when the semiconductor wafer 6 has a smaller size in the thickness direction, and the protective portion 7 is more likely to foam when the semiconductor wafer 6 has a size in the thickness direction of 60 μm or less, for example.

The protective portion 7 can foam when the laser light has an intensity at which the semiconductor wafer 6 is at a temperature of approximately 1200° C. The temperature of the semiconductor wafer 6 during laser annealing tends to increase with increasing intensity of the laser light, so that the protective portion 7 is more likely to foam when the laser light has an intensity greater than the intensity at which the semiconductor wafer 6 is at a temperature of approximately 1200° C.

The stage 1 and the semiconductor wafer 6 are in intimate contact with each other in the vacuum suction region. An unillustrated cooling apparatus is provided on a side of the lower surface of the stage 1, for example. Thus, in the vacuum suction region, the stage 1 and the semiconductor wafer 6 are in intimate contact with each other, so that the semiconductor wafer 6 is likely to be cooled.

On the other hand, in a region around the vacuum suction region, the stage 1 and the semiconductor wafer 6 are not in intimate contact with each other, so that the semiconductor wafer 6 is less likely to be cooled. In the region around the vacuum suction region, the stage 1 and the semiconductor wafer 6 are close to each other, so that heat is likely to build up between the stage 1 and the semiconductor wafer 6. The protective portion 7 is thus particularly likely to foam in the region around the vacuum suction region. A region in which the protective portion 7 is particularly likely to foam is the foaming region B.

Once the protective portion 7 foams, the protective portion 7 is likely to stick to the stage 1. Once the foaming protective portion 7 sticks to the stage 1, removal of the semiconductor wafer 6 from the stage 1 is made difficult. The semiconductor wafer sticks to the stage and is not removed from the stage when being removed from the stage after heat treatment, so that one-sided lifting, which is removal of only a portion of the semiconductor wafer from the stage, conventionally might occur to cause breakage of the semiconductor wafer.

The semiconductor wafer sticks to the stage and is not removed from the stage when being removed from the stage after heat treatment, so that one-sided lifting, which is removal of only a portion of the semiconductor wafer from the stage, might occur to prevent proper delivery of the semiconductor wafer to a transfer apparatus to transfer the semiconductor wafer to thereby stop the transfer apparatus.

The rigid based non-stick material 8 can reduce the likelihood that the semiconductor wafer 6 sticks to the stage 1 when the protective portion 7 foams. That is to say, the semiconductor manufacturing apparatus 101 includes the rigid based non-stick material 8, so that sticking of the semiconductor wafer 6 to the stage 1 is reduced, and the likelihood of breakage of the semiconductor wafer 6 and the likelihood of the stop of the transfer apparatus can be reduced. The semiconductor manufacturing apparatus 101 includes the rigid based non-stick material 8 particularly around the vacuum suction region in which the protective portion 7 is likely to foam, so that the likelihood that the semiconductor wafer 6 sticks to the stage 1 when the protective portion 7 foams can further be reduced.

A deterioration region C is a region in which the rigid based non-stick material 8 provided to the stage 1 is likely to be deteriorated. The rigid based non-stick material 8 is heat sensitive and can be deteriorated by being subjected to heat treatment. That is to say, non-stickiness can be reduced. A portion close to the end 5 of the stage 1 is particularly likely to be exposed to the laser light, so that the rigid based non-stick material 8 is likely to be deteriorated in the portion.

When the rigid based non-stick material 8 is deteriorated, an effect of reducing sticking of the semiconductor wafer 6 to the stage 1 when the protective portion 7 foams is reduced to increase the likelihood that the semiconductor wafer 6 sticks to the stage 1.

As illustrated in FIG. 4, in the semiconductor manufacturing apparatus 101 according to the present embodiment, the foaming region B is provided not to overlap the deterioration region C. The foaming region B does not overlap the deterioration region C, so that the protective portion 7 does not foam in the deterioration region C to reduce the likelihood that the semiconductor wafer 6 sticks to the stage 1. That is to say, the semiconductor wafer 6 can easily be removed from the stage 1. The likelihood of breakage of the semiconductor wafer 6 and the likelihood of the stop of the transfer apparatus can thereby be reduced.

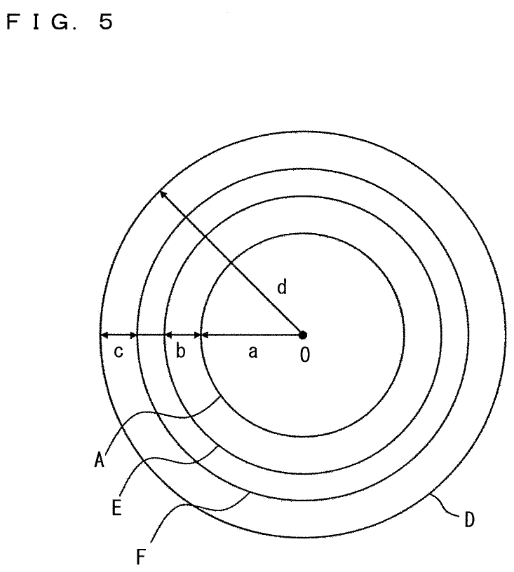

FIG. 5 is a diagram for describing the vacuum suction region of the semiconductor manufacturing apparatus 101 according to Embodiment 1. FIG. 5 schematically shows a surface where the stage 1 and the semiconductor wafer 6 are in contact with each other. In FIG. 5, circles A, D, E, and F are concentric circles having the center O. The circle A has a radius a, the circle D has a radius d, the circle E has a radius e, and the circle F has a radius f. The vacuum suction region is a region in the circle A. A direction toward the center O is an inward direction, and a direction away from the center O is an outward direction.

The foaming region B is generated around the vacuum suction region. The foaming region B is generated in a portion approximately 20 mm around the vacuum suction region. The foaming region B in which the protective portion 7 foams has a width b. In FIG. 5, since the vacuum suction region is the region in the circle A, the foaming region B is a region surrounded by a line indicating a circumference of the circle E, which is a circle having a radius greater than the radius of the circle A by b, and a line indicating a circumference of the circle A. The foaming region B is an annular region generated outside the vacuum suction region, for example.

The deterioration region C is generated in a portion approximately 20 mm inward from an outer circumference of the semiconductor wafer 6. The deterioration region C in which the rigid based non-stick material 8 is deteriorated has a width c. When the semiconductor wafer 6 is assumed to be a circle having the radius d and thus overlapping the circle D, the deterioration region C is a region surrounded by a line indicating a circumference of the circle F, which is a circle having a radius smaller than the radius of the circle D by c, and a line indicating a circumference of the circle D in FIG. 5. The deterioration region C is an annular region generated inside the outer circumference of the semiconductor wafer 6, for example.

The protective portion 7 is likely to foam around the vacuum suction region, so that the foaming region B is determined depending on the vacuum suction region. That is to say, a change in position of the vacuum suction region changes a position of the foaming region B. That is to say, the position of the foaming region B can be adjusted by adjusting the position of the vacuum suction region. When the vacuum suction region is a small region relative to the semiconductor wafer 6, the foaming region B and the deterioration region C do not overlap each other as illustrated in FIG. 5, so that the protective portion 7 does not foam in the deterioration region C, and the likelihood that the semiconductor wafer 6 sticks to the stage 1 can be reduced. That is to say, the semiconductor wafer 6 can easily be removed from the stage 1. The likelihood of breakage of the semiconductor wafer 6 and the likelihood of the stop of the transfer apparatus can thereby be reduced.

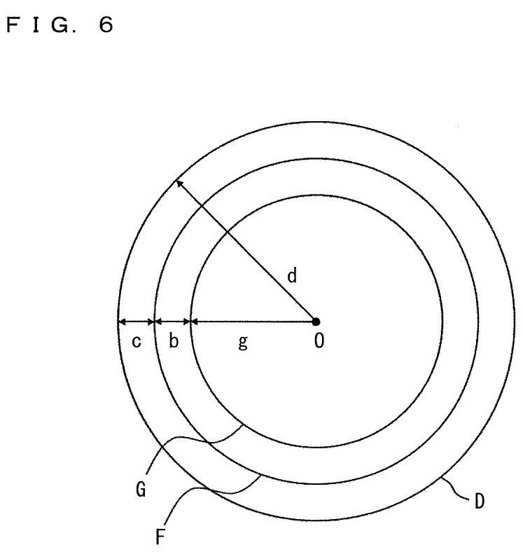

FIG. 6 is a diagram for describing the vacuum suction region of the semiconductor manufacturing apparatus 101 according to Embodiment 1. FIG. 6 schematically shows a surface where the stage 1 and the semiconductor wafer 6 are in contact with each other. In FIG. 6, circles D, F, and G are concentric circles having the center O. The circle D has a radius d, the circle F has a radius f, and the circle G has a radius g.

The rigid based non-stick material 8 is deteriorated in the deterioration region C having the width c extending inward from the outer circumference of the semiconductor wafer 6. That is to say, the deterioration region C is a region surrounded by the line indicating the circumference of the circle F, which is a circle having a radius smaller than the radius of the circle D by c, and the line indicating the circumference of the circle D.

The protective portion 7 foams in the foaming region B having the width b extending outward from an outer circumference of the vacuum suction region. When the foaming region B is generated immediately inside the deterioration region C, the foaming region B is a region surrounded by a line indicating a circumference of the circle G, which is a circle having a radius smaller than the radius of the circle F by b, and the line indicating the circumference of the circle F.

The vacuum suction region is only required to be fitted within the circle G having the radius g indicated by g={d−(b+c)} so that the foaming region B and the deterioration region C do not overlap each other. That is to say, the vacuum suction region is only required to be fitted within a circle having a radius that is {d−(b+c)}/d times the radius of the semiconductor wafer 6 and being concentric with the semiconductor wafer 6. The vacuum suction region is only required to have a sufficient area to fix the semiconductor wafer 6 to the stage 1. That is to say, the vacuum suction region has a radius that is {d−(b+c)}/d times the radius of the semiconductor wafer 6 and has an area substantially enabling fixation of the semiconductor wafer 6 to the stage 1.

In the present embodiment, a semiconductor wafer having any size can be used. When a 12-inch semiconductor wafer is used, for example, the vacuum suction region is only required to be fitted within a circle having a radius that is 11/15 times the radius of the semiconductor wafer and being concentric with the semiconductor wafer, assuming that d is 150 mm, b is 20 mm, and c is 20 mm.

When an 8-inch semiconductor wafer is used, the vacuum suction region is only required to be fitted within a circle having a radius that is ⅗ times the radius of the semiconductor wafer and being concentric with the semiconductor wafer, assuming that d is 100 mm, b is 20 mm, and c is 20 mm.

When a 6-inch semiconductor wafer is used, the vacuum suction region is only required to be fitted within a circle having a radius that is 7/15 times the radius of the semiconductor wafer and being concentric with the semiconductor wafer, assuming that d is 75 mm, b is 20 mm, and c is 20 mm.

The vacuum suction region is fitted within the circle having the radius that is {d−(b+c)}/d times the radius of the semiconductor wafer 6 and being concentric with the semiconductor wafer 6, so that the foaming region B can be brought closer to the center of the stage 1, and thus the foaming region B and the deterioration region C do not overlap each other. That is to say, the protective portion 7 can be prevented from foaming in the deterioration region C. Thus, the likelihood that the semiconductor wafer 6 sticks to the stage 1 can be reduced, and the semiconductor wafer 6 can easily be removed from the stage 1. The likelihood of breakage of the semiconductor wafer 6 and the likelihood of the stop of the transfer apparatus can thus be reduced.

The vacuum suction region is fitted within the circle having the radius that is {d−(b+c)}/d times the radius of the semiconductor wafer 6 and being concentric with the semiconductor wafer 6, so that the foaming region B can be brought closer to the center of the stage 1, and thus, even if the semiconductor wafer 6 sticks to the stage 1 in the foaming region B, the semiconductor wafer 6 is easily removed from the stage 1 because the foaming region B is generated close to the lift pins 2 provided in the central portion of the stage 1.

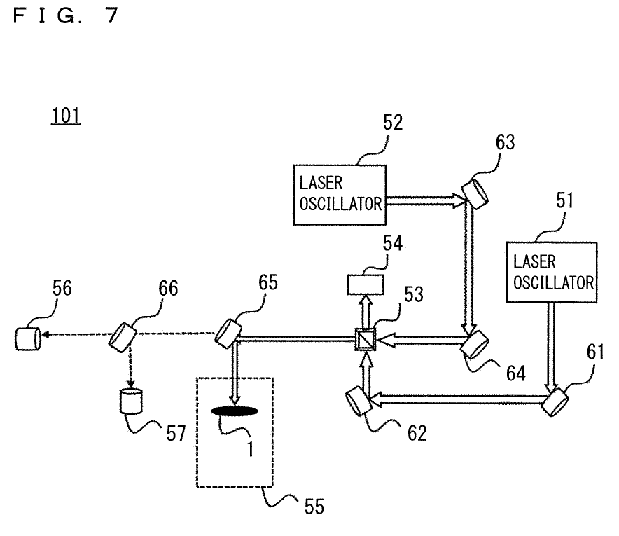

FIG. 7 is a diagram showing a configuration of the semiconductor manufacturing apparatus 101 according to Embodiment 1. The semiconductor manufacturing apparatus 101 includes the stage 1 and the laser apparatus. The laser apparatus includes a first laser oscillator 51, a second laser oscillator 52, a splitter 53, a first measuring member 54, a chamber 55, a profiler 56, a photo director 57, a mirror 61, a mirror 62, a mirror 63, a mirror 64, a mirror 65, and a mirror 66.

The first laser oscillator 51 and the second laser oscillator 52 each output laser light. The laser light output from the first laser oscillator 51 is reflected by the mirror 61 and the mirror 62 and reaches the splitter 53. The laser light output from the second laser oscillator 52 is reflected by the mirror 63 and the mirror 64 and reaches the splitter 53. The splitter 53 overlap the laser light output from the first laser oscillator 51 and the laser light output from the second laser oscillator 52. The splitter 53 also splits the overlapped laser light in two directions.

The laser light overlapped by the splitter 53 is split in two directions by the splitter 53. The laser light split in one direction reaches the first measuring member 54. The laser light split in the other direction reaches the mirror 65 and is further split in two directions.

The laser light split in one direction by the mirror 65 reaches the chamber 55. The stage 1 is provided in the chamber 55. The semiconductor wafer 6 is mounted to the upper surface of the stage 1. The semiconductor wafer 6 provided to the upper surface of the stage 1 is irradiated with the laser light reaching the chamber 55.

The laser light split in the other direction by the mirror 65 is further split in two directions by the mirror 66. The laser light split in one direction by the mirror 66 reaches the profiler 56 as a second measuring member. The laser light split in the other direction by the mirror 66 reaches the photo director 57.

The first laser oscillator 51 and the second laser oscillator 52 output pulsed laser beams with time difference. The first laser oscillator 51 and the second laser oscillator 52 output pulsed laser beams having a wavelength of 300 nm to 600 nm, for example. The pulsed laser beams output from the first laser oscillator 51 and the second laser oscillator 52 are the second harmonics of an Nd:YLF laser having a wavelength of 572 nm, for example. The number of laser oscillators may not be two. One laser oscillator may be provided, or three or more laser oscillators may be provided.

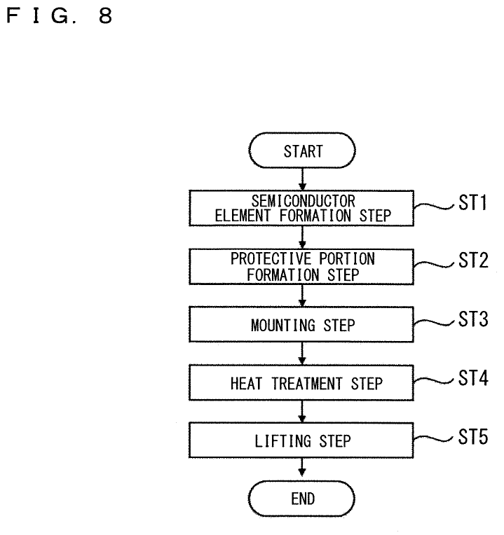

A method of manufacturing a semiconductor device will be described next. FIG. 8 is a flowchart showing the method of manufacturing the semiconductor device according to Embodiment 1. A semiconductor element formation step (ST1) of forming semiconductor elements in the semiconductor wafer 6 is performed first. The semiconductor element formation step includes an ion implantation step of implanting impurity ions into a surface to be the upper surface or the lower surface of the semiconductor wafer 6 and the like. The semiconductor elements formed in the semiconductor wafer 6 are power semiconductors. The power semiconductors include diode elements and switching elements, for example.

Silicon can be used for formation of the semiconductor wafer 6, for example. A wide bandgap semiconductor having a wider bandgap than silicon, such as a material including silicon, silicon carbide, and gallium nitride, a material including gallium oxide, and diamond, can be used for formation of the semiconductor wafer 6, for example.

A protective portion formation step (ST2) of forming the protective portion 7 in the surface of the semiconductor wafer 6 is performed next to protect the surface of the semiconductor wafer 6. The protective portion 7 is formed of a resin, for example. The protective portion 7 may be formed of a material other than the resin as long as the material is insulating.

A mounting step (ST3) of mounting the semiconductor wafer 6 to the upper surface of the stage 1 of the semiconductor manufacturing apparatus 101 is performed next. When the semiconductor wafer 6 is mounted to the upper surface of the stage 1, the semiconductor wafer 6 is mounted to the stage 1 so that the protective portion 7 of the semiconductor wafer 6 is on a side of the stage 1.

A heat treatment step (ST4) of irradiating the semiconductor wafer 6 with the laser light output from the laser apparatus of the semiconductor manufacturing apparatus 101 is performed next. Heat treatment performed in step ST4 is particularly lase annealing. In the heat treatment step, the impurity ions implanted into the semiconductor wafer 6 are activated.

The heat treatment step is required to be performed at a high power. The high power is a power of 1 W or more, for example. Heat treatment performed at a high power increases the likelihood that the protective portion 7 foams, but sticking of the semiconductor wafer 6 to the stage 1 can be suppressed by using the semiconductor manufacturing apparatus 101 according to the present embodiment. Sticking of the semiconductor wafer 6 to the stage 1 can be suppressed, so that removal of the semiconductor wafer 6 from the stage 1 is facilitated to improve productivity of the semiconductor device.

When the semiconductor wafer 6 formed of a wide bandgap semiconductor, such as SiC, is heat treated, laser annealing is performed at a temperature higher than that for silicon, so that the semiconductor wafer 6 is at a temperature of approximately 1200° C. The semiconductor wafer 6 at a temperature of approximately 1200° C. increases the likelihood that the protective portion 7 foams, but sticking of the semiconductor wafer 6 to the stage 1 can be suppressed by using the semiconductor manufacturing apparatus 101 according to the present embodiment. Sticking of the semiconductor wafer 6 to the stage 1 can be suppressed, so that removal of the semiconductor wafer 6 from the stage 1 is facilitated to improve the productivity of the semiconductor device.

In the heat treatment step (ST4), the semiconductor wafer 6 can be irradiated with the laser light at an angle of less than 90°. Irradiation of the semiconductor wafer 6 with the laser light at an angle of less than 90° can suppress damage of the laser apparatus by the laser light reflected by the semiconductor wafer 6. Irradiation of the semiconductor wafer 6 at an angle of less than 90° means that the semiconductor wafer 6 is irradiated with the laser light at an angle of approximately 80° to 89°, for example. That is to say, it means that the semiconductor wafer 6 is irradiated with the laser light tilted approximately 1° to 10°.

In the heat treatment step (ST4), the semiconductor wafer 6 can be irradiated perpendicularly with the laser light. Perpendicular irradiation of the semiconductor wafer 6 with the laser light can suppress direct irradiation of the rigid based non-stick material 8 of the stage 1 with the laser light. Deterioration of the rigid based non-stick material 8 can thus be suppressed. Sticking of the semiconductor wafer 6 to the stage 1 can thus be suppressed to facilitate removal of the semiconductor wafer 6 from the stage 1. Perpendicular irradiation of the semiconductor wafer 6 includes not only irradiation of the semiconductor wafer 6 at an angle of 90° but also irradiation of the semiconductor wafer 6 at an angle that can suppress deterioration of the rigid based non-stick material 8.

A surface of the stage 1 to be in contact with the semiconductor wafer 6 may be smaller than a surface of the semiconductor wafer 6 to be in contact with the stage 1. The surface of the stage 1 to be in contact with the semiconductor wafer 6 smaller than the surface of the semiconductor wafer 6 to be in contact with the stage 1 can suppress direct irradiation of the rigid based non-stick material 8 with the laser light. Deterioration of the rigid based non-stick material 8 can thus be suppressed. Sticking of the semiconductor wafer 6 to the stage 1 can thus be suppressed to facilitate removal of the semiconductor wafer 6 from the stage 1.

A lifting step (ST5) of lifting the lift pins 2 from a side of the lower surface to a side of the upper surface of the stage 1 to remove the semiconductor wafer 6 from the stage 1 is performed next. In the lifting step (ST5), the semiconductor manufacturing apparatus 101 can lift the semiconductor wafer 6 at a time.

In the lifting step (ST5), the semiconductor manufacturing apparatus 101 can lift the lift pins 2 stepwise separate times. For example, the semiconductor manufacturing apparatus 101 can lift the lift pins 2 by 0.5 mm, stop lifting for five seconds, and, after stopping lifting for five seconds, lift the lift pins 2 again by 0.5 mm. Lifting and the stop of lifting of the lift pins 2 can be repeated any number of times. The lift pins 2 can be lifted stepwise separate times, so that the semiconductor wafer 6 can gradually be removed from the stage 1 even when the semiconductor wafer 6 sticks to the stage 1. Breakage of the semiconductor wafer 6 can thus be suppressed.

The semiconductor manufacturing apparatus 101 can also reduce a speed of lifting of the lift pins 2. The speed of lifting of the lift pins 2 is reduced, so that the semiconductor wafer 6 can gradually be removed from the stage 1 even when the semiconductor wafer 6 sticks to the stage 1. Breakage of the semiconductor wafer 6 can thus be suppressed.

The semiconductor manufacturing apparatus 101 according to the present embodiment includes the stage 1 to which the semiconductor wafer 6 including the protective portion 7 and irradiated with the laser light is mounted so that the protective portion 7 is in contact with the stage 1, the stage 1 having the vacuum suction region in which the semiconductor wafer 6 is fixed, the stage 1 including the rigid based non-stick material 8 provided on a side to be in contact with the protective portion 7 of the semiconductor wafer 6, wherein the vacuum suction region is fitted within the circle having the radius that is {d−(b+c)}/d times the radius of the semiconductor wafer 6 and being concentric with the semiconductor wafer 6, where d (mm) is the radius of the semiconductor wafer 6, b (mm) is the width of the foaming region B in which the protective portion 7 foams, c (mm) is the width of the deterioration region C in which the rigid based non-stick material 8 is deteriorated, so that the semiconductor wafer 6 can easily be removed from the stage 1.

A method of manufacturing the semiconductor device according to the present embodiment includes: the protective portion formation step of forming the protective portion 7 in the semiconductor wafer 6; the mounting step of mounting the semiconductor wafer 6 to the stage 1 including the rigid based non-stick material 8 and having the vacuum suction region so that the protective portion 7 is in contact with the rigid based non-stick material 8, the vacuum suction region being fitted within the circle having the radius that is {d−(b+c)}/d times the radius of the semiconductor wafer 6 and being concentric with the semiconductor wafer 6, where d (mm) is the radius of the semiconductor wafer 6, b (mm) is the width of the foaming region B in which the protective portion 7 foams, c (mm) is the width of the deterioration region C in which the rigid based non-stick material 8 is deteriorated; the heat treatment step of heat treating the semiconductor wafer 6 by irradiating the semiconductor wafer 6 with the laser light from the side opposite the side to be in contact with the stage 1; and the lifting step of moving the lift pins 2 of the stage 1 to remove the semiconductor wafer 6 from the stage 1, so that the semiconductor wafer 6 can easily be removed from the stage 1.

In the above-mentioned embodiment described herein, material properties of, materials for, dimensions of, shapes of, a relative positional relationship among, or conditions for implementation of components are sometimes described, but they are examples in all aspects, and are not restrictive. Numerous unillustrated modifications are thus devised within the scope of the embodiment. For example, a case where any component is modified, added, or omitted and, further, a case where at least one component in at least one embodiment is extracted to be combined with components in another embodiment are included.

While the preferred embodiment and the like have been described in detail above, the above-mentioned embodiment and the like are not restrictive and can be modified and replaced without departing from the scope described in the claims.

Various aspects of the present disclosure will collectively be described below as appendices.

### Appendix 1

A semiconductor manufacturing apparatus comprising
a stage to which a semiconductor wafer including a protective portion and irradiated with laser light is mounted so that the protective portion is in contact with the stage, the stage having a vacuum suction region in which the semiconductor wafer is fixed, the stage including a rigid based non-stick material provided on a side to be in contact with the protective portion of the semiconductor wafer, wherein
the vacuum suction region is fitted within a circle having a radius that is {d−(b+c)}/d times a radius of the semiconductor wafer and being concentric with the semiconductor wafer, where d (mm) is the radius of the semiconductor wafer, b (mm) is a width of a foaming region in which the protective portion foams, c (mm) is a width of a deterioration region in which the rigid based non-stick material is deteriorated.

### Appendix 2

The semiconductor manufacturing apparatus according to Appendix 1, wherein
when the semiconductor wafer is a 12-inch semiconductor wafer, the vacuum suction region is fitted within a circle having a radius that is 11/15 times the radius of the semiconductor wafer and being concentric with the semiconductor wafer.

### Appendix 3

The semiconductor manufacturing apparatus according to Appendix 1, wherein
when the semiconductor wafer is an 8-inch semiconductor wafer, the vacuum suction region is fitted within a circle having a radius that is ⅗ times the radius of the semiconductor wafer and being concentric with the semiconductor wafer.

### Appendix 4

The semiconductor manufacturing apparatus according to Appendix 1, wherein
when the semiconductor wafer is a 6-inch semiconductor wafer, the vacuum suction region is fitted within a circle having a radius that is 7/15 times the radius of the semiconductor wafer and being concentric with the semiconductor wafer.

### Appendix 5

The semiconductor manufacturing apparatus according to any one of Appendices 1 to 4, wherein
the stage has a suction hole to suck the semiconductor wafer.

### Appendix 6

The semiconductor manufacturing apparatus according to any one of Appendices 1 to 5, wherein
a surface of the stage to be in contact with the semiconductor wafer is smaller than a surface of the semiconductor wafer to be in contact with the stage.

### Appendix 7

The semiconductor manufacturing apparatus according to any one of Appendices 1 to 6, wherein
the stage includes, in the vacuum suction region, a lift pin to move the semiconductor wafer away from the stage.

### Appendix 8

The semiconductor manufacturing apparatus according to any one of Appendices 1 to 7, wherein
the rigid based non-stick material includes a material containing silicon and oxygen.

### Appendix 9

The semiconductor manufacturing apparatus according to any one of Appendices 1 to 8, further comprising
a laser apparatus to irradiate the semiconductor wafer with the laser light.

### Appendix 10

A method of manufacturing a semiconductor device, the method comprising:
a protective portion formation step of forming a protective portion in a semiconductor wafer;
a mounting step of mounting the semiconductor wafer to a stage including a rigid based non-stick material and having a vacuum suction region so that the protective portion is in contact with the rigid based non-stick material, the vacuum suction region being fitted within a circle having a radius that is {d−(b+c)}/d times a radius of the semiconductor wafer and being concentric with the semiconductor wafer, where d (mm) is the radius of the semiconductor wafer, b (mm) is a width of a foaming region in which the protective portion foams, c (mm) is a width of a deterioration region in which the rigid based non-stick material is deteriorated;
a heat treatment step of heat treating the semiconductor wafer by irradiating the semiconductor wafer with laser light from a side opposite a side to be in contact with the stage; and
a lifting step of moving a lift pin of the stage to remove the semiconductor wafer from the stage.

### Appendix 11

The method of manufacturing the semiconductor device according to Appendix 10, wherein
the stage has a suction hole to suck the semiconductor wafer.

### Appendix 12

The method of manufacturing the semiconductor device according to Appendix 10 or 11, wherein
in the lifting step, the lift pin is lifted separate times.

### Appendix 13

The method of manufacturing the semiconductor device according to any one of Appendices 10 to 12, wherein
in the heat treatment step, the semiconductor wafer is irradiated perpendicularly with the laser light.

While the invention has been shown and described in detail, the foregoing description is in all aspects illustrative and not restrictive. It is therefore understood that numerous modifications and variations can be devised without departing from the scope of the invention.

What is claimed is:

1. A semiconductor manufacturing apparatus comprising
a stage to which a semiconductor wafer including a protective portion and irradiated with laser light is mounted so that the protective portion is in contact with the stage, the stage having a vacuum suction region in which the semiconductor wafer is fixed, the stage including a rigid based non-stick material provided on a side to be in contact with the protective portion of the semiconductor wafer, wherein
the vacuum suction region is fitted within a circle having a radius that is {d−(b+c)}/d times a radius of the semiconductor wafer and being concentric with the semiconductor wafer, where d (mm) is the radius of the semiconductor wafer, b (mm) is a width of a foaming region in which the protective portion foams, c (mm) is a width of a deterioration region in which the rigid based non-stick material is deteriorated.

2. The semiconductor manufacturing apparatus according to claim 1, wherein
when the semiconductor wafer is a 12-inch semiconductor wafer, the vacuum suction region is fitted within a circle having a radius that is 11/15 times the radius of the semiconductor wafer and being concentric with the semiconductor wafer.

3. The semiconductor manufacturing apparatus according to claim 1, wherein
when the semiconductor wafer is an 8-inch semiconductor wafer, the vacuum suction region is fitted within a circle having a radius that is ⅗ times the radius of the semiconductor wafer and being concentric with the semiconductor wafer.

4. The semiconductor manufacturing apparatus according to claim 1, wherein
when the semiconductor wafer is a 6-inch semiconductor wafer, the vacuum suction region is fitted within a circle having a radius that is 7/15 times the radius of the semiconductor wafer and being concentric with the semiconductor wafer.

5. The semiconductor manufacturing apparatus according to claim 1, wherein
the stage has a suction hole to suck the semiconductor wafer.

6. The semiconductor manufacturing apparatus according to claim 1, wherein
a surface of the stage to be in contact with the semiconductor wafer is smaller than a surface of the semiconductor wafer to be in contact with the stage.

7. The semiconductor manufacturing apparatus according to claim 1, wherein
the stage includes, in the vacuum suction region, a lift pin to move the semiconductor wafer away from the stage.

8. The semiconductor manufacturing apparatus according to claim 1, wherein
the rigid based non-stick material includes a material containing silicon and oxygen.

9. The semiconductor manufacturing apparatus according to claim 1, further comprising
a laser apparatus to irradiate the semiconductor wafer with the laser light.

10. A method of manufacturing a semiconductor device, the method comprising:
a protective portion formation step of forming a protective portion in a semiconductor wafer;
a mounting step of mounting the semiconductor wafer to a stage including a rigid based non-stick material and having a vacuum suction region so that the protective portion is in contact with the rigid based non-stick material, the vacuum suction region being fitted within a circle having a radius that is {d−(b+c)}/d times a radius of the semiconductor wafer and being concentric with the semiconductor wafer, where d (mm) is the radius of the semiconductor wafer, b (mm) is a width of a foaming region in which the protective portion foams, c (mm) is a width of a deterioration region in which the rigid based non-stick material is deteriorated;
a heat treatment step of heat treating the semiconductor wafer by irradiating the semiconductor wafer with laser light from a side opposite a side to be in contact with the stage; and
a lifting step of moving a lift pin of the stage to remove the semiconductor wafer from the stage.

11. The method of manufacturing the semiconductor device according to claim 10, wherein
the stage has a suction hole to suck the semiconductor wafer.

12. The method of manufacturing the semiconductor device according to claim 10, wherein
in the lifting step, the lift pin is lifted separate times.

13. The method of manufacturing the semiconductor device according to claim 10, wherein
in the heat treatment step, the semiconductor wafer is irradiated perpendicularly with the laser light.
